(19) United States
(12) Patent Application Publication
(10) Pub. No.: US 2008/0134961 A1
(43) Pub. Date: Jun. 12, 2008

(54) SINGLE-CRYSTAL ORGANIC SEMICONDUCTOR MATERIALS AND APPROACHES THEREFOR

(76) Inventors: Zhenan Bao, Stanford, CA (US); Alejandro L. Briseno, Seattle, WA (US); Colin C. Reese, Stanford, CA (US); Stefan C. B. Mannsfeld, Palo Alto, CA (US); Shuhong Liu, Stanford, CA (US); Mang-Mang Ling, Palo Alto, CA (US)

Correspondence Address: CRAWFORD MAUNU PLLC, 1150 NORTHLAND DRIVE, SUITE 100, ST. PAUL, MN, 55120, US

(21) Appl. No.: 11/932,057

(22) Filed: Oct. 31, 2007

Related U.S. Application Data
(60) Provisional application No. 60/856,702, filed on Nov. 3, 2006.

(51) Int. Cl. C30B 23/00; H01L 51/00

(52) U.S. Cl. 117/86; 257/40; 257/E51.001

(57) ABSTRACT

Patterned single crystals and related devices are facilitated. According to an example embodiment of the present invention, organic semiconducting single-crystals are manufactured using a plurality of surface regions on a substrate. The diffusivity and/or the rate of desorption is controlled at each surface region and at the substrate to grow at least one organic semiconducting single crystal at each surface region from a vapor-phase organic material. This control is effected, for example, before and/or during the introduction of vapor-phase organic material to the surface regions. In some embodiments, the surface regions include an organic film such as octadecyltriethoxysilane (OTS), and in other embodiments, the surface regions include carbon nanotube bundles, either of which can be implemented to exhibit a surface roughness and/or other characteristics that facilitate selective crystal nucleation.

### RELATED PATENT DOCUMENTS

This patent document claims the benefit, under 35 U.S.C. §119(e), of U.S. Provisional Patent Application Ser. No. 60/856,702, entitled Single-crystal Organic Semiconductor Materials and Approaches Therefor and filed on Nov. 3, 2006, which is fully incorporated herein by reference.

### FEDERALLY-SPONSORED RESEARCH AND DEVELOPMENT

This invention was made with Government support under contract AFOSR F49620-03-1-0101 awarded by the U.S. Air Force and contract DMR-0213618 awarded by the National Science Foundation. The U.S. Government has certain rights in this invention.

### FIELD OF THE INVENTION

The present invention relates generally to semiconductor devices, and more particularly to arrangements and approaches involving organic semiconductors.

### BACKGROUND

Semiconductor device applications have experienced significant scaling (reduction in size) over recent years, with continued scaling desirable for a multitude of applications. In addition, semiconductors and semiconductor devices are increasingly used in cross-disciplinary applications, in various configurations, and in unique operating environments.

Many semiconductor applications involve and/or would benefit from the use and implementation of organic semiconductor materials. Organic single-crystal field-effect transistors are useful for the study of charge transport in organic semiconductor materials. In addition, their high performance and outstanding electrical characteristics make them desirable for implementation with electronic applications such as active matrix displays or sensor arrays. For example, organic field-effect transistors are often implemented with organic thin-film transistors (OTFT, or OTFTs). OTFTs are useful for performing a variety of functions and offer unique characteristics desirable for many applications. See, e.g., Sze, S. M. Semiconductor Devices: Physics and Technology, 2nd edition; Wiley: New York, 1981. Generally, OTFTs are low in weight, flexible in application and inexpensive; as such, OTFTs are useful for a multitude of applications. Other organic semiconductor structures include organic light-emitting diodes, organic lasers, organic solar cells and organic biosensors.

One aspect of the implementation of organic semiconductor single crystal materials relates to the manufacture of such materials in a desirable arrangement and/or size. For example, previous approaches to the manufacture of organic materials have been generally limited to the formation of layers or films of organic materials. Approaches to sizing or arranging organic materials have been generally tedious, time-consuming and expensive. In addition, such layers or films are not readily implemented for use with certain applications benefiting from certain shape, orientation or arrangement of organic single crystal materials. In particular, organic single crystal materials are not readily implemented for manufacture on a relatively large scale.

The size and arrangement of semiconductor devices continue to be important to a variety of functional and physical aspects of device implementation, to achieve such aspects such as those relating to desirable speed and to physical size constraints. However, devices located in close proximity are susceptible to a variety of conditions that can be undesirable.

One undesirable condition relating to the interaction between nearby semiconductor devices involves cross-talk, where operational characteristics of one device affect one or more adjacent devices in close proximity (e.g., via capacitive, inductive or conductive coupling). As devices are scaled smaller, cross-talk issues can become more challenging. One approach to reducing or minimizing cross-talk between neighboring devices involves separation of semiconductor materials, such as by patterning an active semiconductor layer. However, with single-crystal organic semiconductor materials, there is often a need to hand-select individual crystals, which presents challenges to producing single crystal devices at high density and with reasonable throughput. In particular, while arrays of inorganic crystals have been patterned over large areas, patterning discrete organic molecular crystals has been particularly challenging.

These and other issues have been challenging to the design, manufacture and implementation of semiconductor devices, and in particular, for those semiconductor devices employing organic semiconductor materials.

### SUMMARY

The present invention is directed to overcoming the above-mentioned challenges and others related to the types of applications discussed above and in other applications. These and other aspects of the present invention are exemplified in a number of illustrated implementations and applications, some of which are shown in the figures and characterized in the claims section that follows.

According to an example embodiment of the present invention, single-crystals of an organic semiconductor material are provided for one or more of a variety of applications, using a plurality of surface regions on a substrate. While applying a vapor-phase organic material at the surface regions, the diffusivity of the surface regions is controlled to grow at least one organic semiconducting single crystal at each surface region from the vapor-phase organic material.

According to another example embodiment of the present invention, an array of organic single-crystal semiconductor devices is manufactured. An array of surface regions are provided on a substrate, and a vapor-phase organic material is applied to the array of surface regions. The diffusivity of each surface region is controlled, and at least one organic single crystal is grown from the vapor-phase organic material as a function of the controlled diffusivity. With this approach, an array of organic single crystals is formed at the surface regions.

In some applications, the organic single crystals are formed as part of a circuit, connecting two circuit nodes such as source and drain electrodes of a transistor. The single crystals provide a semiconducting connection that is useful, for example, in gated transistors, diodes, photovoltaic devices, solar cells or lasers.

In connection with other example embodiments, an organic semiconductor device arrangement includes a substrate, an array of growth regions and, at each growth region, at least one organic semiconductor single-crystal. The growth regions exhibit a surface diffusivity that facilitates growth of the at least one organic semiconductor single-crystal. In some applications, the device arrangement includes a plurality of semiconductor devices in an array, each using the single crystals as a circuit portion. In various embodiments, the at least one organic semiconductor single crystal forms a portion of an electronic circuit for a device such as of field-effect transistor, a diode, a photovoltaic device, a solar cell or a laser.

The above summary is not intended to describe each illustrated embodiment or every implementation of the present invention.

### BRIEF DESCRIPTION OF THE DRAWINGS

The invention may be more completely understood in consideration of the detailed description of various embodiments of the invention that follows in connection with the accompanying drawings, in which:

FIG. 1A-1D show an array of single-crystal organic semiconductor material at various stages of manufacture, according to an example embodiment of the present invention, in which

FIG. 1A shows a stamp for applying a thin film to a substrate,

FIG. 1B shows a substrate upon which the thin film is to be printed,

FIG. 1C shows the substrate in FIG. 1B after printing, and

FIG. 1D shows an array of single-crystals grown at each of the printed films;

FIG. 2 shows an array of Pentacene crystals, according to another example embodiment of the present invention;

FIG. 3 shows an array of Rubrene crystals, according to another example embodiment of the present invention;

FIG. 4 shows an array of Fullerene C₆₀ crystals, according to another example embodiment of the present invention;

FIG. 5 shows a flexible semiconductor device with an arrayed pattern of molecular organic crystals, according to another example embodiment of the present invention;

FIG. 6 is a flow diagram for an approach to orienting organic single-crystals, according to another example embodiment of the present invention;

FIG. 7 shows a portion of a device having single-crystal growth regions, according to another example embodiment of the present invention; and

FIG. 8 shows example surface roughness characteristics as implemented to facilitate the growth of single-crystals, according to another example embodiment of the present invention.

While the invention is amenable to various modifications and alternative forms, examples thereof have been shown by way of example in the drawings and will be described in detail. It should be understood, however, that the intention is not to limit the invention to the particular embodiments shown and/or described. On the contrary, the intention is to cover all modifications, equivalents, and alternatives falling within the spirit and scope of the invention.

### DETAILED DESCRIPTION

The present invention is believed to be applicable to a variety of different types of processes, devices and arrangements organic semiconductor materials. While the present invention is not necessarily so limited, various aspects of the invention may be appreciated through a discussion of examples using this context.

According to an example embodiment of the present invention, an approach to semiconductor device manufacture involves the fabrication and implementation of arrays of patterned organic single crystals. A thin film is formed on a substrate (e.g., printed onto a substrate) to obtain patterned growth regions (i.e., thin film surface regions at individual patterned locations on the substrate). The growth regions exhibit a diffusivity that facilitates organic single crystal growth and are formed using one or more of a variety of approaches, such as microcontact-printing. The substrate and patterned growth regions are exposed to an organic material vapor at conditions amenable to crystal growth, and organic single crystals are grown at each of the growth regions to produce an array of single crystals. This approach facilitates the growth of organic single crystals for a variety of implementations, such as in forming semiconductor regions implemented with electronic devices such as transistors, diodes (e.g., LEDs), lasers or solar cells.

In various example embodiments of the present invention, different thin films and organic materials are used to suit different applications. In one example embodiment, thin film domains of octadecyltriethoxysilane (OTS) are printed onto a clean Si/SiO₂ substrate surface in a pattern and having a size to fit a particular application in which subsequently-grown single-crystal organic materials are to be implemented. Using the thin film domains, organic single crystals are vapor-grown, with the nucleation of the single crystals restricted to the printed OTS domains. This patterning approach facilitates the growth of crystals directly onto desirable circuit locations, such as for use with the applications discussed above. For instance, one or more single crystals grown at a particular growth region can be used as an organic transistor channel region, extending between source/drain electrodes for implementation in field-effect transistor arrangements. With this approach (and, as appropriate, with similar printing applications involving materials other than OTS films and Si/SiO₂ substrates), relatively large arrays of high-performance organic single-crystal transistors are formed with active regions having mobilities as high as 2.4 cm²/Vs and on/off ratios greater than 10⁷. In addition, single crystals are manufactured on flexible substrates using this approach (e.g., capable of bending to a radius of about 6 mm).

In another example embodiment, a carbon nanotube films are patterned at growth locations to promote the growth of single-crystals. Single-walled carbon nanotube (SWNT) bundles are formed in an array, and one or more of a multitude of organic semiconductor materials, such as p-type pentacene, tetracene, sexiphenylene, and sexithiophene, and n-type tetracyanoquinodimethane (TCNQ), can be grown from the bundles. The quantity of SWNT bundles can be used to set the number of crystals. This approach is applicable to crystal growth with transistor source-drain electrodes and arrays of organic single-crystal field effect transistors, and to applications in optoelectronics.

In connection with another example embodiment of the present invention, and as may be implemented in connection with one or more aspects of the embodiments described herein and/or shown in the figures, a temperature (or range of temperature) at which to grow single-crystal organic material is selected as follows. This temperature may, for example, be selected in accordance with a particular roughness exhibited by growth regions, formed on a substrate.

A reference material such as pentacene is used in selecting a starting temperature for growing single crystals from a particular type of organic material. The melting point or molecular weight of the reference is compared with the melting point of the particular type of organic material and, from the comparison, a starting temperature is selected.

Using this starting temperature, the particular organic material is introduced to a growth arrangement (e.g., by introducing a vapor of the organic material to patterned growth regions) and the growth arrangement is observed for single crystal growth. If no growth is observed (e.g., after a certain time period, such as 30 minutes), the temperature is increased and the organic material vapor is again introduced to a growth arrangement. In some applications, the temperature is increased by a selected amount, such as by about 25° F., at a particular time interval. This approach involving observation and increase in temperature is repeated until crystal growth is observed.

Once crystal growth is observed, the temperature is raised and/or lowered by relatively smaller amount (e.g., a few degrees Fahrenheit), with growth at these temperatures also observed. This approach to raising and/or lowering the temperature at relatively smaller amounts is repeated until desirable single-crystal growth is observed (e.g., while mitigating nucleation that would result in film growth across the substrate, instead of single-crystal growth limited to the growth regions).

In connection with another example embodiment of the present invention, organic single crystals are grown at a particular orientation on a substrate. In some applications, the single crystals are aligned by rubbing and/or abrading growth regions upon which the organic single crystals are grown. The rubbing and/or abrading facilitates the directional orientation of the single crystals in one or more of a variety of manners, such as by effecting a geometric arrangement of the growth regions (e.g., forming grooves in the growth regions), aligning molecules on the surface of the growth regions, or electrostatically charging the growth regions. For example, certain embodiments are directed to the formation of growth regions having a particular directional characteristic, such as grooves in a particular direction, using growth approaches and/or physically altering as-grown regions with an abrasive material. Where multiple growth regions are formed on a substrate, different single-crystal orientations can be obtained by forming growth regions with different physical characteristics or simply by rubbing different growth regions in different directions.

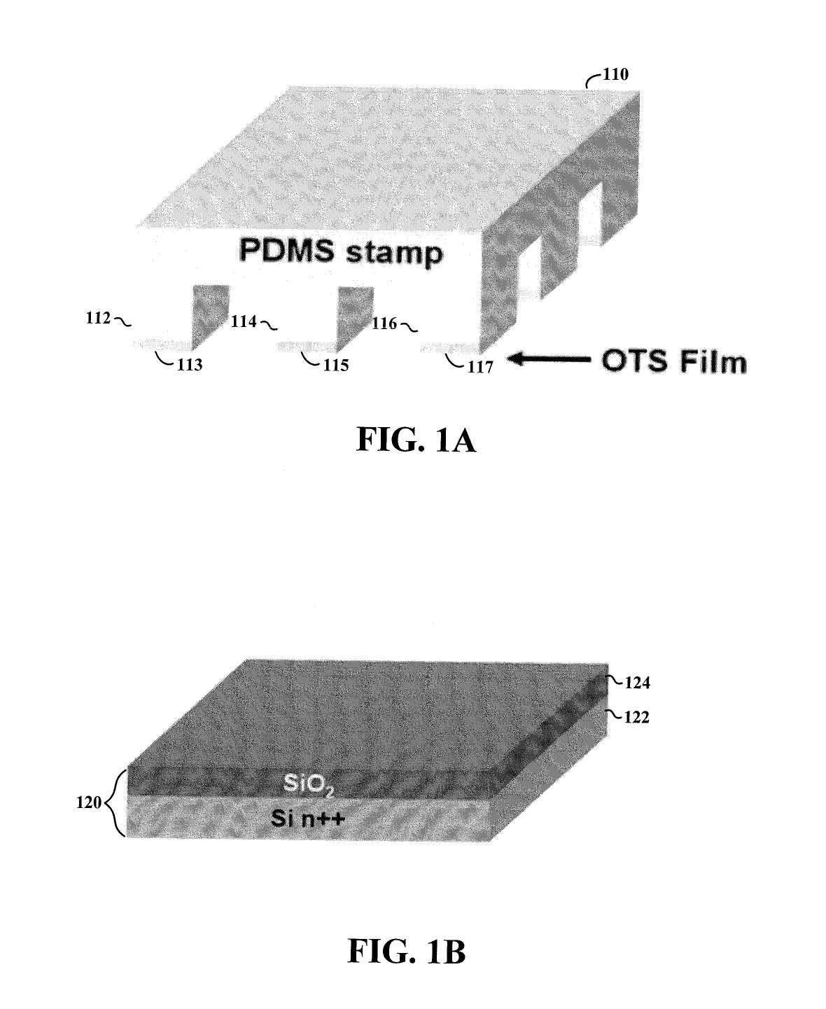

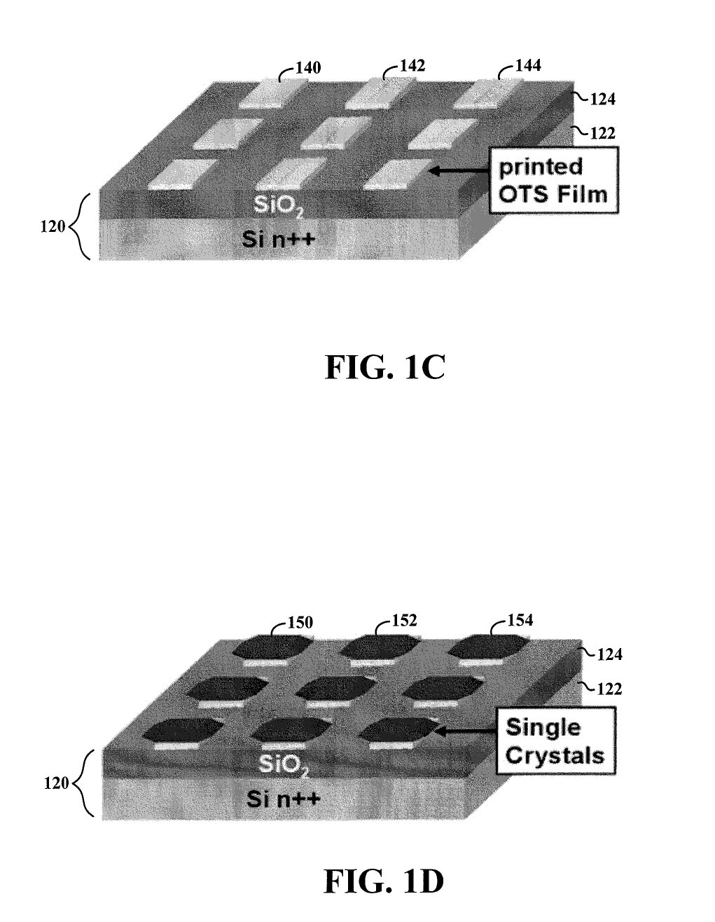

Turning now to the Figures, FIGS. 1A-1D show an array of single-crystal organic semiconductor material at various stages of manufacture, according to another example embodiment of the present invention. Beginning with FIG. 1A, a polydimethylsiloxane (PDMS) stamp 110 includes relief features, including features 112, 114 and 116, that are amenable to coating (e.g., inking) with a film (113, 115 and 117) and subsequent application of the film to a substrate. Using the approach described above by way of example, a thick film may be inked onto the relief features of the PDMS stamp 110, using a material such as OTS. In some applications, characteristics of the stamp are used to facilitate a roughness or other characteristic of the printed film.

FIG. 1B shows a substrate 120 including a Si n⁺⁺ layer 122 and an SiO₂ layer 124, upon which the PDMS stamp 110 is adapted for printing the film inked on the stamp. Referring back to FIG. 1A, the PDMS stamp 110 applies the film coated on each of its features in an arrangement defined by those features, as shown in FIG. 1C. For instance, referring to the features 112, 114 and 116, the PDMS stamp 110 is adapted for applying a film in a generally rectangular shape, spaced and oriented as shown in FIG. 1A, with the resulting patterned film shown in FIG. 1C, with individual patterned portions 140, 142 and 144 shown by way of example. In some applications, the patterned film is formed with a nominal thickness of about 13±2 nm using a microcontact printing approach.

In connection with the approaches shown in FIG. 1A and FIG. 1B, as well as with one or more other embodiments, the selective nucleation of single crystals is controlled by the roughness of a thick stamped film (e.g., OTS) on a substrate. In some applications, a film having an RMS roughness of about 150 Å is formed as stamped domains. In other applications, the stamped domains have a surface with peak-to-valley values of about 120 nm, and in other applications, the peak-to-valley distance is at least the height needed to form an initial nucleus for single crystal growth. For example, for pentacene, this is about 2-3 molecular layers and equal to about 3-5 nm). In certain applications, the substrate 120 has a surface that is smooth, relative to the stamped film, to mitigate single-crystal growth on the substrate 120 during growth on the stamped film. Relative to FIG. 1C, the resulting patterned film portions (e.g., 140, 142 and 144) can be formed having roughness in accordance with these approaches.

In some embodiments, the patterned film in FIG. 1C is a carbon nanotube film, applied using a similar approach (a transfer printing process) or another approach that facilitates the placement of the carbon nanotubes. For instance, a chloroform dispersion of single-walled nanotube (SWNT) bundles can be spray-coated onto the PDMS stamp 110, grown from the substrate 124 or embedded in the substrate 124. The nanotubes form a rough and/or uneven surface at each growth regions, facilitating interaction with organic materials. Where appropriate, the nanotube bundles are located at electrodes, such as source-drain electrodes, to facilitate crystalline growth for connecting electrodes.

In some applications, polymers are absorbed to the carbon nanotubes via π-π interactions (e.g., noncovalent organic interactions via intermolecular overlapping) between the nanotubes with π-conjugated segments such as pentacene, which can lead to nucleation of organic molecules onto SWNTs. For instance, pentacene may be initially absorbed in a relatively flat geometry on nanotube surfaces and subsequently rotated into an edge-on geometry once a sufficient number of molecules are present for the formation of a small nucleus. In these contexts, the π-π interactions may be used to effectively amplify the effect of the rough topography of nanotube bundles, relative to promoting crystal growth. For general information regarding carbon nanotubes, and for specific information regarding interactions with carbon nanotubes as may be implemented to facilitate the nucleation of organic molecules, reference may be made to P. F. Qi, A. Javey, M. Rolandi, Q. Wang, E. Yenilmez and H. J. Dai, J. Am. Chem. Soc. 2004, 126, 11774, which is fully incorporated herein by reference.

The substrate 120 with the patterned film portions as shown in FIG. 1C is placed in a vacuum at a selected temperature (e.g., elevated, relative to room temperature), and an organic source material in a vapor phase is introduced to the substrate 120. For instance, in one particular embodiment, the substrate 120 is placed in a vacuum-sealed tube (e.g., at a vacuum of about 0.38 mmHg) together with an organic source material, and then into a gradient sublimation furnace for growth of patterned single crystals.

FIG. 1D shows the substrate 120 with an array of single-crystals of organic semiconductor material formed at each of the patterned locations. By way of example, three single crystals 150, 152 and 154 are shown corresponding to the patterned locations 140, 142 and 144 in FIG. 1C. These crystals are generally limited in location to the patterned film (or nanotube bundle) locations, and exhibit desirably high crystalline form (see, e.g., Appendix A in the above-referenced provisional application for characterization of different crystals in connection with one or more example embodiments). Characteristics of this approach and the arrangement as shown in FIGS. 1A-1D such as size, shape and arrangement of the printed film portions, the density of the film (e.g., of a SWNT dispersion) temperature and organic material are controlled to facilitate nucleation control to grow a desired number of single crystals (e.g., 1, 2 or more) at each patterned location. Once formed, the organic single crystals are readily implemented for one or more semiconductor applications as described herein.

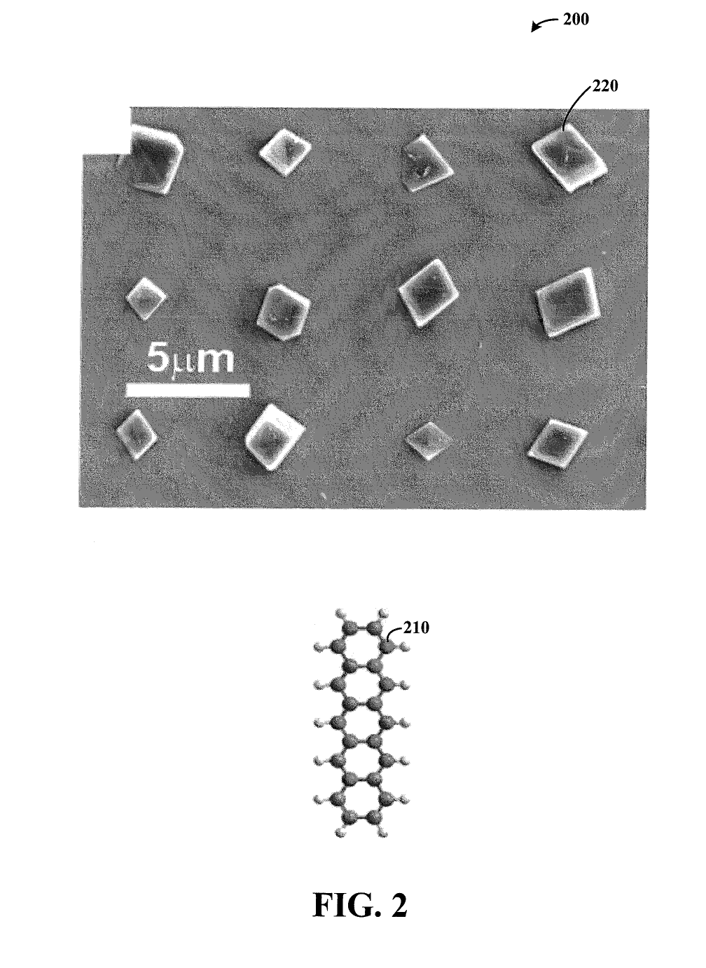

A variety of organic source materials are used in various embodiments. In some implementations, high mobility p-type materials such as rubrene, pentacene, and tetracene are used. In other implementations, n-type materials such as C₆₀, fluorinated copper phthalocyanine (Fl₆CuPc), and tetracyanoquinodimethane (TCNQ) are used. FIGS. 2-4 show various approaches with different materials, and are described further below.

In other example embodiments, a relatively high substrate temperature is used to achieve selective crystal growth (in connection with FIGS. 1A-1D or otherwise). In some applications, the substrate temperature is maintained at a temperature of about 20° C. lower than a temperature of the evaporation source to facilitate a relatively high thermal redesorption rate and a high energetic barrier to the formation of a stable nucleus in bare substrate (e.g., SiO₂) regions (e.g., having an RMS roughness of less than about 5 Å). The nucleation of crystals is effectively suppressed in these substrate regions, with the patterned locations, which are rough relative to the bare substrate, facilitating single crystal nucleation.

Referring again to FIG. 1D, in some implementations, the organic source material is placed in a hot region of a furnace while the patterned substrate is positioned in a cooler deposition region. For example, one implementation is directed to the use of a pentacene organic source at a temperature that is maintained at about 260° C., and the closest edge of the patterned substrate 120 is positioned about 2 cm away from the source zone (e.g., at about 250° C.). The nucleation zone of pentacene crystals extends to a far edge of the substrate 120 at about 5 cm away from the source (e.g., at about 220° C.). Using such an approach, sublimation and crystal growth occurs in as little as five minutes for pentacene; using a similar approach for C₆₀, sublimation and crystal growth occur in as much as two hours.

Notwithstanding the stamp 110 shown in FIG. 1A, for various example embodiments, stamps similar to that shown in FIG. 1A are implemented with one or more of a variety of feature shapes, sizes and arrangements relative to one another to suit the particular implementation for which single-crystals are formed. Similarly, a variety of substrates are amenable to use with this approach, using materials including and/or different than those shown for the substrate 120. Appendix A in the above-referenced provisional application shows and/or describes various example embodiments involving approaches similar to the above, in connection with FIGS. 1A-1D, applicable with different materials.

By providing particular control to the diffusivity of surface regions on the substrate, organic semiconducting single-crystals can be grown at the particular surface locations while inhibiting their growth at other surface locations. In certain embodiments having various surface compositions, such as a substrate printed with thin film domains, the diffusivity is controlled to facilitate this organic single-crystal growth at the domains, where large-scale nucleation (e.g., of polycrystalline film growth) is mitigated. In some applications, this diffusivity is facilitated by controlling conditions such as temperature, surface material (and any corresponding molecular interaction), surface roughness, vacuum level and/or other atmospheric conditions. In certain more specific embodiments, a desirable surface diffusivity is effected by setting the roughness of the surface of the growth regions, using materials that facilitate the formation of rough regions and/or altering regions that have already been formed, such as by abrasion. For different applications, the diffusivity levels and/or rate of desorption of the surfaces are controlled at different levels to achieve this organic single-crystal growth. FIG. 1C is useful to represent various ones of these applications.

FIG. 2 shows an arrangement 200 with an array of Pentacene crystals, according to another example embodiment of the present invention. Pentacene crystal 220 is numbered by way of example, and is formed in connection with a patterning and vapor-phase growth approach as described, for example, in FIGS. 1A-1D above. Each single crystal, including the Pentacene crystal 220, includes a Pentacene structure 210. By way of example, a marking of 5 μm is shown relative to the spacing of the crystals for this embodiment.

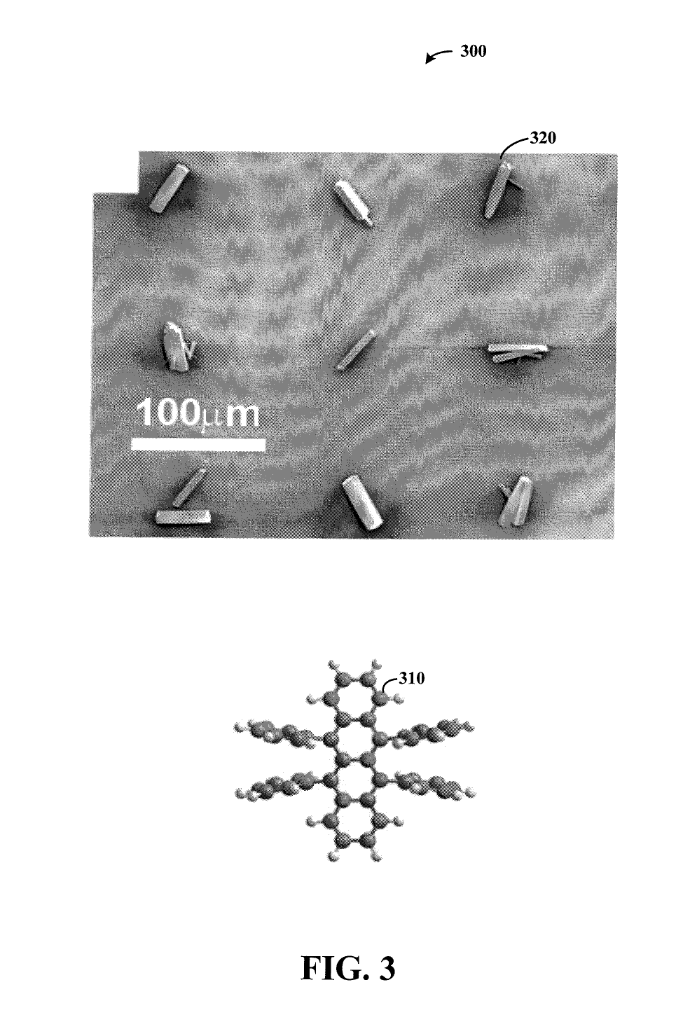

FIG. 3 shows an arrangement 300 with an array of Rubrene crystals, according to another example embodiment of the present invention. Rubrene crystal 320 is numbered by way of example, and is formed in connection with a patterning and vapor-phase growth approach as described, for example, in FIGS. 1A-1D above. Each single crystal, including the Rubrene crystal 320, includes a Rubrene structure 310. By way of example, a marking of 100 μm is shown relative to the spacing of the crystals for this embodiment.

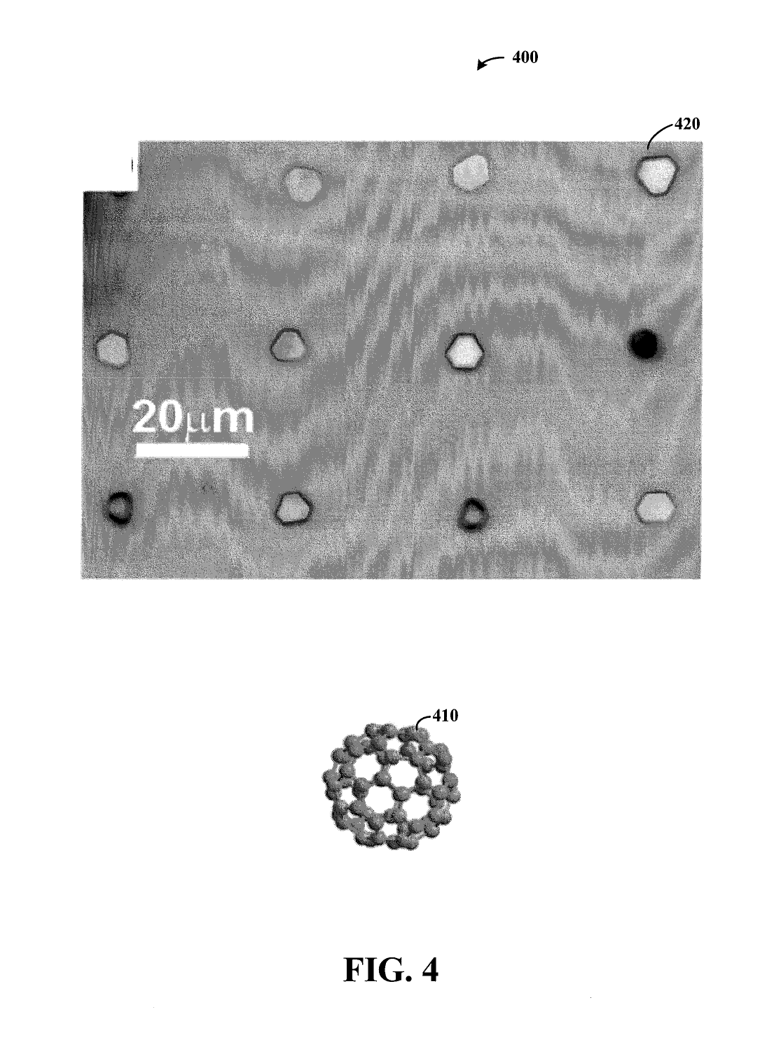

FIG. 4 shows an arrangement 400 with an array of Fullerene C₆₀ crystals, according to another example embodiment of the present invention. Fullerene C₆₀ crystal 420 is numbered by way of example, and is formed in connection with a patterning and vapor-phase growth approach as described, for example, in FIGS. 1A-1D above. Each single crystal, including the Fullerene C₆₀ crystal 420, includes a Fullerene C₆₀ structure 410. By way of example, a marking of 20 μm is shown relative to the spacing of the crystals for this embodiment.

In each of the embodiments shown in FIGS. 2-4, an appropriate stamp feature size is chosen to set the number of single crystals at each patterned location (domain), from one to many single crystals. For instance, relative to FIG. 2, the dependency of the Pentacene nucleation activity on the size of the stamped OTS domains is exemplified in that a stamp of about 5×5 μm in area yields one single crystal per domain. Similarly, a SWNT bundle having an area of about 8×8 μm to 9×9 μm exhibits a single crystal per bundle. In addition, for various applications, the orientation of the single crystals, relative to a reference point, is controlled as shown or otherwise to achieve desirable operational or other characteristics. This orientation may be facilitated via the stamp feature size and/or orientation.

In connection with another example embodiment of the present invention, a patterning approach as described above is implemented for the growth of large arrays of crystals directly onto transistor channel regions between source-drain electrodes (e.g., for a field-effect transistor or FET). In a manner similar to that described with FIG. 3, Rubrene single crystals are patterned into a 14×14 transistor array with a few crystals between each pair of source and drain electrodes. In some instances, a single Rubrene crystal bridges the channel region of a transistor. The devices exhibit mobility values ranging from about 0.1 to 2.4 cm²/Vs, with average saturation regime mobilities of about 0.6±0.5 cm²/Vs with on/off ratios greater than 10⁷. Referring to FIG. 2, Pentacene single crystal transistors are similarly fabricated in connection with a similar approach and embodiment, with mobilities on the order of about 0.3 cm²/Vs and on/off ratios greater than about 10⁵ are obtained from unpurified Pentacene source material. In still other applications, n-channel materials such as C₆₀ and TCNQ are also patterned with mobilities of 0.03 and 10⁻⁴ cm²/Vs, respectively. Appendix A in the above-referenced provisional application describes various approaches and implementations relative to these example embodiments, involving the formation of Rubrene, Pentacene and n-channel materials as described.

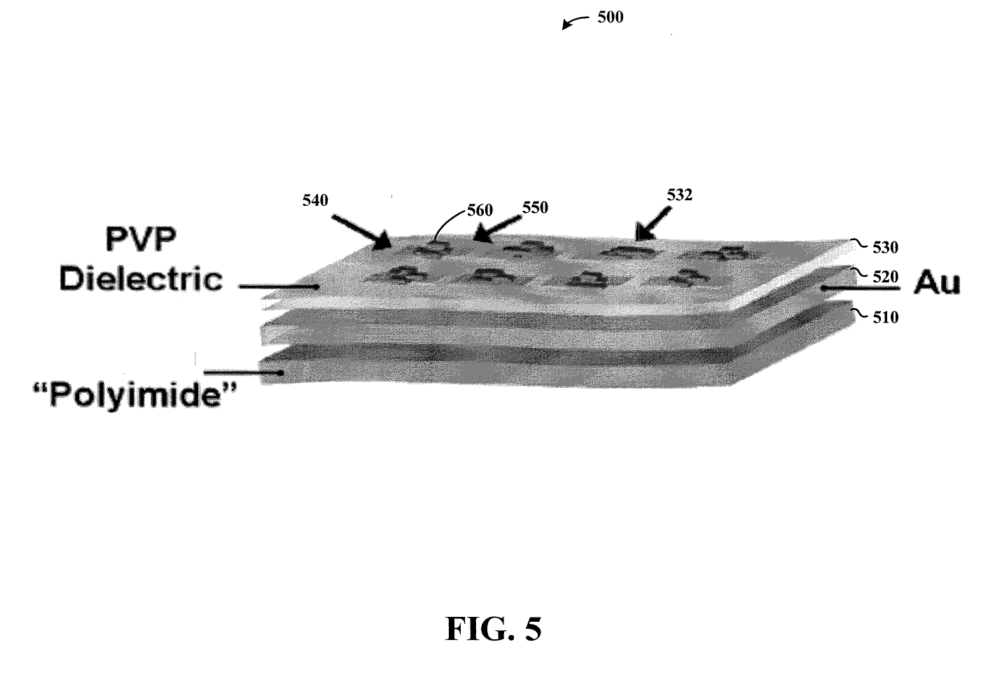

FIG. 5 shows a flexible semiconductor device 500 with an arrayed pattern of molecular organic crystals for an array of transistors, according to another example embodiment of the present invention. A polyimide substrate 510, such as the Kapton® polyimide available from DuPont, with a gold layer 520 and a poly-4-vinylphenol (PVP) dielectric layer 530 form a flexible substrate (with shown gaps between layers by way of example). A plurality of single-crystals, including single crystal 532, is grown in a patterned arrangement on the PVP dielectric 530. Each transistor includes a source and a drain region, with source 540 and drain 550 labeled by way of example, with organic single crystals 560 bridging the source and drain, forming a channel region therebetween. Other applications are directed to the formation of a single crystal that makes up the channel region (e.g., where only one relatively large crystal is formed at the location of the crystals 560).

In one embodiment, the PVP dielectric layer 530 is spin-coated at about 2,000 rpm on a 140 μm-thick DuPont Kapton® (polyimide) sheet 510 covered with a 100 nm gold coating 520 used for the gate electrode (available, for example, from Astral Technology Unlimited, Inc. of Northfield, Minn.). A dielectric solution is prepared from a 22 wt % PVP, and 8 wt % poly(melamine-co-formaldehyde)methylated (Mw=511). The substrate is baked at about 100° C. for about 10 minutes then at about 200° C. for about 10 minutes to provide crosslinking of the dielectric solution to form the PVP layer 530. Source and drain electrodes (e.g., 540 and 550) are formed by thermal evaporation of Chromium (about 1.5 nm) and Gold (about 50 nm). In some applications, a glass substrate is used as a heat sink to prevent the plastic substrate 510 from warping under high temperatures.

With the approaches shown in FIG. 5 and described above, field effect mobilities as high as 0.9 cm²/Vs and on/off ratios of about 10³ are obtained for various implementations, at a threshold voltage of about 1.5 V. In addition, the device 500 is amenable to bending to radii of about 6 mm during operation. In other applications, high vapor pressure materials such as anthracene and/or tetracene are used in addition to and/or in place of the Rubrene.

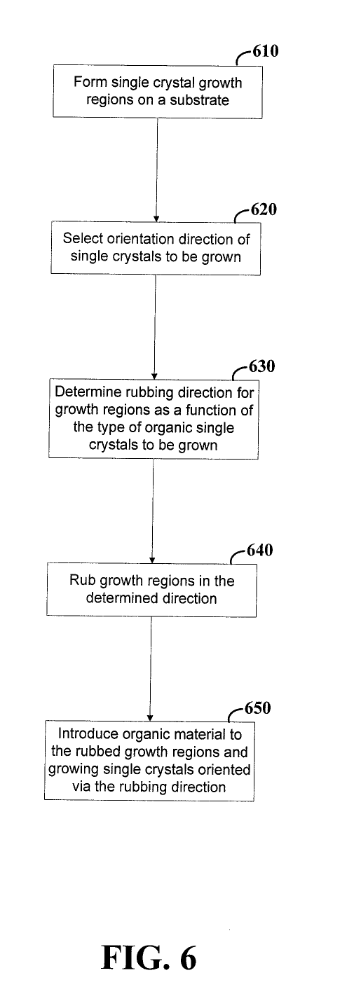

FIG. 6 is a flow diagram for an approach to orienting organic single-crystals, according to another example embodiment of the present invention. As discussed above, physical characteristics of a substrate or other growth region can be modified to orient single-crystal growth in accordance with various embodiments. The approach shown in FIG. 6 is directed to a physical alteration of growth regions (e.g., after their formation), with subsequent growth of organic single-crystal materials.

At block 610, a plurality of growth regions are formed on a substrate. In some applications, the growth regions are formed in a manner not inconsistent with those approaches described above, including those approaches shown in and described in connection with FIGS. 1A-1C, using a film such as OTS or a SWNT bundle. In some applications, a substrate having growth regions is provided, and block 610 is omitted.

At block 620, a desirable orientation direction of organic single crystals is selected, relative to the type of growth regions, to an intended application of the single crystals (e.g., as a channel region for semiconductor device), or to other characteristics of the growth and/or implementation of the organic single crystals.

At block 630, a direction for rubbing is selected, relative to the type of organic single crystal material to be grown and the desired application for which the organic single crystals are implemented. In connection with this approach, it has been discovered that certain organic single crystals orient in a particular direction, relative to the rubbing of growth regions. In this regard, known or otherwise estimated orientation directions for particular organic materials are used in selecting a rubbing direction, to achieve a desirable orientation for a particular application or applications for which the single crystals are to be used. In some applications, such an orientation is selected to achieve selected charge transport characteristics that are related to the orientation of single crystals in an array.

At block 640, growth regions are rubbed in the selected rubbing direction, either individually or as a group, and in one or more selected directions as appropriate for the particular application. After rubbing, an organic material is introduced to the growth regions and organic single crystals are grown at block 650.

As described above, the rubbing implemented at block 640 is used to effect orientation in one or more of a variety of manners. In connection with one embodiment, a physical alignment approach involves aligning organic single crystals by rubbing the growth regions at block 640 to physically modify the surface of the growth regions and/or to align molecules at the surface. One such approach involves rubbing the growth regions in a particular direction with one or more of a material having a relatively low coefficient of friction such as Polytetrafluoroethylene (PTFE) or Teflon® (available from DuPont), or a material similar to the material making up the growth regions. For instance, by rubbing a PTFE bar (cross section) across a substrate five times in single direction, oriented organic single crystal growth is achieved. Similarly, with thin films (e.g., 5-10 nm evaporated films), a cheese cloth can be used to rub the surface of the thin films 2-3 times to achieve oriented organic single crystal growth. In some implementations, the growth regions are preheated (e.g., to about 200° C.) prior to rubbing or other abrasion.

Different types of organic single crystals grown at block 650 orient in different directions relative to the rubbing at block 640. For instance, α-sexiphenylene (6p), α-sexithiophene (6T), biphenylene-terthiophene-biphenylene (PPTTTPP) single crystals orient in a direction that is perpendicular to a rubbing direction. Organic TCNQ single crystals orient slightly perpendicular to the rubbing direction. Organic 2-(4-isopropoxyphenyl)-5-(5-(5-(4-isopropoxyphenyl)thiophen-2-yl)thiophen-2-yl)thiophene (IPOP3TP) single crystals show both perpendicular and parallel orientation to the rubbing, with generally more single crystals oriented in a perpendicular direction, relative to those single crystals oriented in a parallel direction. Organic dichlorotetracene single crystals orient in a generally parallel direction, relative to the rubbing. Organic pentacene, tetracene and anthracene do not necessarily orient in any direction, relative to the rubbing. In this regard, various embodiments are directed to the growth of single crystals using these materials and known orientation relative to the rubbing, with the rubbing direction accordingly selected at block 630 (e.g., using a lookup table with the type of organic material used to grow single crystals).

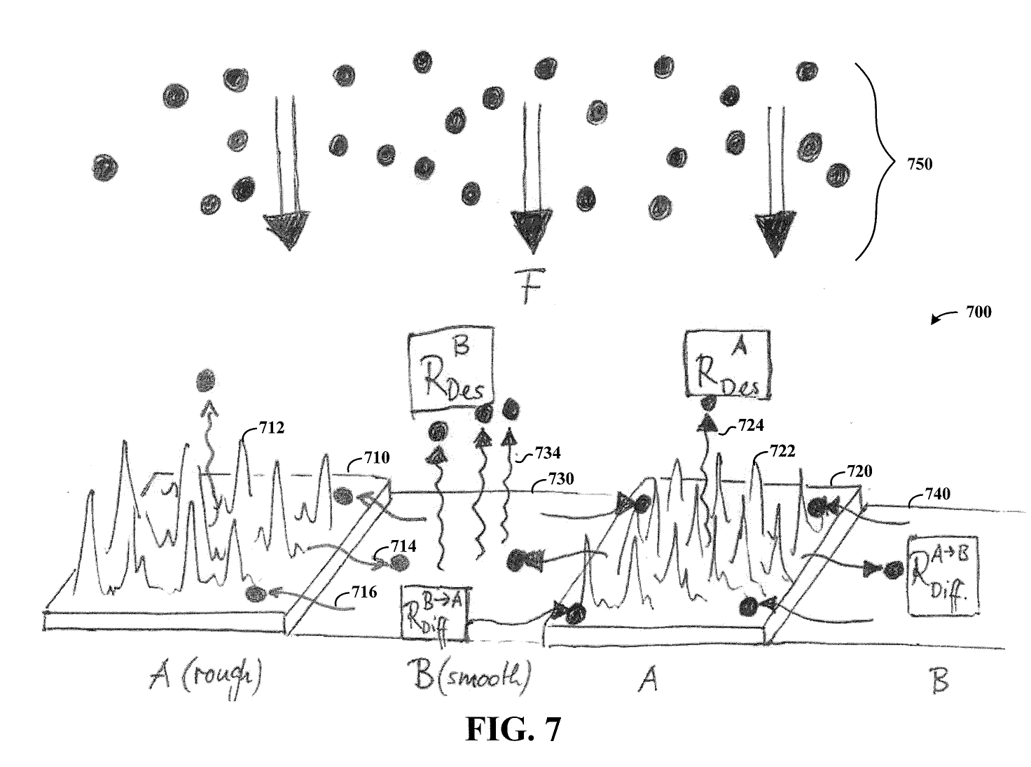

FIG. 7 shows a portion of a device 700 having single-crystal growth regions, according to another example embodiment of the present invention. Surface roughness is controlled to facilitate crystal growth at rough surface regions and to mitigate crystal growth at smooth surface regions, with the roughness of the surface controlled or set to position crystal growth. The growth regions and approaches shown in and described in connection with FIG. 7 may, for example, be implemented in connection with one or more of the various example embodiments described herein. For instance, the diffusivity and/or rate of desorption from growth or other surface regions as described above may be implemented as shown in and/or described in connection with FIG. 7. In this regard, controlling the surface diffusivity of a surface region may involve one or more of controlling the surface roughness, rate of desorption or related growth conditions in a manner not inconsistent with the following.

Two single-crystal growth regions 710 and 720 are shown formed on a substrate having relatively smooth portions 730 and 740 (e.g., an inert or inert-like substrate) separating the growth regions. Each of the single-crystal growth regions 710 and 720 have rough surfaces, characterized by raised portions including portions 712 and 722 labeled for growth regions 710 and 720 by way of example. In some applications, the growth regions 710 and 720 are of a similar or the same material as the relatively smooth portions 730 and 740. Other applications use a material for the growth regions 710 and 720 that is different than the material for the smooth portions 730 and 740.

When an organic single crystal vapor 750 is applied (e.g., introduced) to the device 700, the growth regions 710 and 720 facilitate growth of single crystals, while the smooth regions 730 and 740 of the substrate tend to mitigate growth of the single crystals. In various embodiments, the growth regions 710 and 720 exhibit diffusivity and/or rate of desorption and/or roughness, relative to the smooth regions 730 and 740, which facilitates single-crystal growth that is limited to the growth regions. With these approaches, crystals are grown close to or on the substrate surface, which is useful for devices such as organic field-effect transistors.

In connection with the following discussion, the various expressions are denoted as follows, where “A” corresponds to growth regions (exemplified by regions 710 and 720 in FIG. 7) and “B” corresponds to smooth regions (exemplified by regions 730 and 740 in FIG. 7).

F: Flux of incoming particles/molecules.

R_{Des}_{₁}^{A}R_{Des}^{B}: Rates of desorption from fields (e.g., regions) A and B, respectively.

R_{Diff}_{₁}^{A→B}R_{Diff}^{B→A}: Rates of surface diffusion from A to B and B to A, respectively.

R_{C}: Rate of capture of monomers by existing nuclei

As described by way of example in the following, the rate of diffusivity of the organic material vapor 750 from the growth regions 710 and 720 to the smooth regions 730 and 740 (R_{Diff}^{A→B}) is less than the rate of diffusivity of the organic material vapor from the smooth regions to the growth regions (R_{Diff}^{B→A}). These corresponding rates of desorption are respectively exemplified by arrows 714 and 716 in connection with growth region 710 and smooth region 730. Similarly, the rate of desorption from the growth regions 710, 720 (R_{Des}^{A}) is greater than the rate of desorption from the smooth regions 730 and 740 (R_{Des}^{B}). These corresponding rates of desorption are respectively exemplified by arrows 724 and 734 in connection with the growth region 720 and smooth region 730.

Example rate equations for the monomer densities (N^{A}, N^{B}) in the rough (growth) and smooth (non-growth) regions, characterized using fields A and B, are as follows:

$$\begin{matrix}\frac{d {N}^{A}}{d t} = F - {R}_{Des}^{A} - 2 ( {R}_{Diff}^{A \to B} - {R}_{Diff}^{B \to A} ) - {R}_{C}^{A} , \\ and & Equation 1 \\ \frac{d {N}^{B}}{d t} = F - {R}_{Des}^{B} - 2 ( {R}_{Diff}^{B \to A} - {R}_{Diff}^{A \to B} ) - {R}_{C}^{B} . & Equation 2\end{matrix}$$

A large difference of monomer density between the A and B fields (in favor of the A fields) is used to improve the chance for nucleation in A, relative to B, and therein promoting single-crystal growth in desired regions, while mitigating growth where such growth is undesirable. The following equation 3 represents this difference:

$$\frac{d {N}^{A}}{d t} - \frac{d {N}^{B}}{d t} = ( {R}_{Des}^{B} - {R}_{Des}^{A} + 4 ( {R}_{Diff}^{B \to A} - {R}_{Diff}^{A \to B} ) >> ∅$$

Generally, a desirably large difference in monomer density is achieved when the rate of desorption from A is smaller than the rate of desorption from B, characterized by

R_{Des}^{A}<<R_{Des}^{A} Equation 3

and when the rate of diffusion out of B is significantly larger than the rate of diffusion out of A, characterized by

R_{Diff}^{B→A}>>R_{Diff}^{A→B} Equation 4

In order to suppress nucleation in B completely, the combined rate of desorption from B and diffusion out of B should almost be as large as the flux F of particles and/or molecules introduced to the device (e.g., 750 in FIG. 7), characterized by:

R_{Des}^{B}+R_{Diff}^{B→A}≦F Equation 5

In some embodiments, the relationships denoted by Equations 3 and 4 are facilitated by creating a rough surface topology or a non-smooth surface topology in A, such as described in various example embodiments herein. In other embodiments, the relationship denoted by Equation 5 is facilitated by using a relatively high substrate temperature and a relatively diffusive/smooth surface B.

Referring to FIG. 7 again, for various embodiments, the indicated regions A and B are reversed in diffusivity and/or desorption characteristics. For instance, where the indicated regions 730 and 740 form portions of a substrate, such a substrate is formed (or modified) to facilitate the diffusivity and/or desorption characteristics of regions 710 and 720 via one or more characteristics such as surface roughness, interaction with a particular flux F, temperature-related characteristics or pressure-related characteristics. In such applications, regions 710 and 720 are correspondingly formed with the diffusivity and/or desorption characteristics indicated with the regions 730 and 740 via similar characteristics.

Surfaces 710, 720, 730 and 740, either as shown in FIG. 7 or as described in connection with the reversed approach in the previous paragraph, are formed in one or more of a variety of manners. In some embodiments, surfaces 710 and 720 are printed on a substrate including surfaces 730 and 740, to form rough or smooth surfaces, relative to the substrate, to suit the particular application. In other embodiments, the surfaces 710, 720, 730 and 740 are of a common substrate treated disparately. In one application, a substrate having a rough surface is formed as indicated with regions 710 and 720. These regions 710 and 720 are then masked, and unmasked portions of the substrate are then smoothed (e.g., via etching or another approach) to form smooth regions including regions 730 and 740. As apparent, a multitude of approaches may be implemented to form regions that respectively promote and mitigate single-crystal growth, in small and large arrayed locations, for implementation with different devices, applications and intended uses; the present invention contemplates these approaches with various example embodiments.

In various embodiments, nucleation exclusion or denuded zones, in which crystal nucleation is nearly completely suppressed, are created around stamped domains (e.g., at surfaces 730 and 740 around surface 720) by controlling growth conditions. After initial nucleation, the rate of monomer capture by existing nuclei becomes significant, such that crystals in the stamped domains act as a sink and deplete the immediate vicinity of monomers. In this regard, the size of such exclusion zones is controlled by setting one or more of the surface migration rate in the smooth substrate domains (e.g., as corresponding to the above rate discussion), the flux of monomers impinging on the substrate, and the substrate temperature. The flux of monomers is controlled via the capture of monomers from introduced vapor by crystals at the rough domains, such that the remaining vapor at the smooth substrate regions exhibits a relatively lowered of concentration (i.e., supersaturation level lowered below a value at which the nucleation rate in a steady-state nucleation model is close to zero). The substrate temperature is selectively raised to increase the rate of desorption and surface diffusion length become, which leads to larger exclusion zones (i.e., to a larger distance away from the stamped domains). With these approaches, crystal growth is controlled for a variety of implementations.

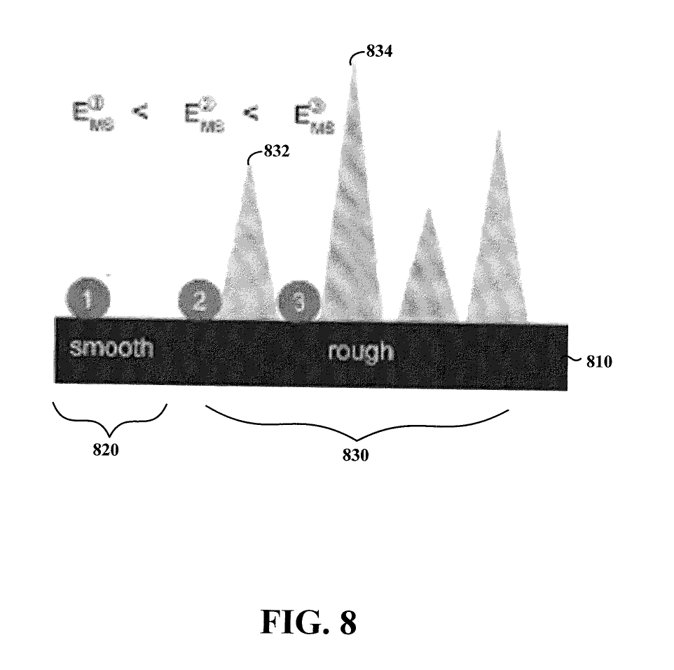

FIG. 8 shows an example substrate 810 exhibiting surface characteristics relative to smooth and rough regions 820 and 830, with the rough region facilitating crystal nucleation, according to another example embodiment. The surface roughness (e.g., surface topography) is controlled or set to facilitate stronger molecule-substrate interactions at the rough region 830. The strength of interaction between molecules and the substrate 810 (denoted as EMS) is greater at rougher regions, with positions 1, 2 and 3 respectively exhibiting increased strength of interaction via relatively tall pillars 832 and 834. In this regard, the roughness of desired growth regions, such as those shown in FIG. 7, is controlled to facilitate the patterned growth of single crystals under various conditions. This growth is around, on or adjacent to pillar-type structures 832 and 834, or as shown in FIG. 7, using surface roughness to control crystal growth.

In one embodiment, a stamp approach similar to that shown in FIGS. 1A-1D is used to print an OTS film (e.g., FIG. 1C) that exhibits desirable surface structure. An OTS ink is used to print the surface regions including those at 140, 142 and 144, using a relatively low viscosity ink with the PDMS stamp 110, and further lifting the PDMS stamp 110 at a rate that leaves behind OTS pillars similar, for example, to those shown in FIG. 7 and in FIG. 8. The viscosity of the ink and stamp lifting speed are selectively tailored to suit particular applications and desirable crystal growth.

While the present invention has been described above and in the claims that follow, those skilled in the art will recognize that many changes may be made thereto without departing from the spirit and scope of the present invention. Such changes may include, for example, the implementation of one or more approaches as described in the list of references in the Appendices included with U.S. Provisional Patent Application Ser. No. 60/856,702, referenced above and fully incorporated herein by reference. Other changes include reversing the relationship between growth regions and a substrate on which they are formed (e.g., by printing relatively smooth surface regions on a relatively rough substrate to promote single-crystal growth on the substrate and mitigate such growth on the printed surface regions). Another change may include forming both growth regions and non-growth regions of a substrate (i.e., forming regions that control diffusivity and/or desorption to respectively promote or mitigate single-crystal growth, either by printing or forming a substrate having the regions therein). In this regard, the approaches discussed herein generally involve forming a substrate with or without additional regions formed thereon, with a portion of a substrate controlled to promote or mitigate single-crystal growth, relative to another portion of the substrate. These and other approaches as described in the contemplated claims below characterize aspects of the present invention.

What is claimed is:

1. A method for manufacturing organic semiconducting single-crystals using a plurality of surface regions on a substrate, the method comprising:
while applying a vapor-phase organic material at the surface regions, controlling at least one of the diffusivity and the rate of desorption at the surface regions and the substrate to grow at least one organic semiconducting single crystal at each surface region from the vapor-phase organic material.

2. The method of claim 1, wherein controlling includes, prior to applying the vapor-phase organic material, forming surface regions having a surface roughness that facilitates organic single-crystal growth at the surface regions.

3. The method of claim 1, wherein controlling includes controlling the vacuum of the environment in which the single crystals are grown.

4. The method of claim 1, wherein controlling includes controlling the temperature of the environment in which the single crystals are grown.

5. The method of claim 1, wherein controlling includes setting the surface diffusivity of the material of the surface regions, prior to applying the vapor-phase organic material.

6. The method of claim 1, further including, prior to growing at least one single crystal, forming the plurality of surface regions on an underlying substrate that mitigates the growth of single crystals, and wherein controlling includes using the surface regions to facilitate single-crystal growth while mitigating crystal growth at the underlying substrate, thereby forming single crystals at the surface regions without forming single crystals on the underlying substrate.

7. The method of claim 1, wherein growing at least one single crystal at each surface region includes using the substrate and the diffusivity characteristics of the surface regions to facilitate the nucleation of organic single crystal material that is limited to the surface regions.

8. The method of claim 1, further including, prior to growing at least one single crystal, forming the plurality surface regions having surface roughness characteristics that facilitate a molecular interaction with the vapor-phase organic material that promotes the growth of organic semiconducting single-crystals at the surface regions.

9. The method of claim 1, further including, prior to growing at least one single crystal, forming the plurality surface regions to exhibit a surface diffusivity that facilitates the nucleation of single-crystals at the surface regions and mitigates the nucleation of a polycrystalline film of the organic material.

10. The method of claim 1, further including controlling the orientation of the at least one organic semiconducting single crystal by rubbing the plurality of surface regions in a direction.

11. The method of claim 1, further including controlling the orientation of the at least one organic semiconducting single crystal by forming grooves in a surface of the surface regions and growing an array of single crystals that are all oriented in a common direction relative to the grooves.

12. The method of claim 1, further including, prior to growing at least one single crystal, forming the plurality surface regions from a material layer having peaks extending from the surface to a height that is controlled to facilitate interaction with the vapor-phase material to effect crystal nucleation at a base of the peaks near the surface.

13. The method of claim 1,
further including forming the plurality surface regions from a carbon nanotube material, prior to growing at least one single crystal, and
wherein controlling at least one of the diffusivity and the rate of desorption at the surface regions and the substrate to grow at least one organic semiconducting single crystal at each surface region from the vapor-phase organic material includes using π-π interactions between the nanotubes and the vapor-phase organic material to effect nucleation at the carbon nanotube material.

14. The method of claim 1, further including, prior to growing at least one single crystal, forming the plurality surface regions from a material layer having peaks extending from the surface to a height that is controlled to set the height of the at least one organic semiconducting singly crystal at each surface region.

15. The method of claim 1, further including, prior to growing at least one single crystal, forming each of the plurality surface regions to a size that is set to control the number of crystals formed at the surface region.

16. The method of claim 1, further including, prior to growing at least one single crystal, forming each of the plurality surface regions by forming an octadecyltriethoxysilane (OTS) film at each of the surface regions and having roughness characteristics that facilitate the nucleation of single crystals at the film.

17. A method for manufacturing an array of organic single-crystal semiconductor devices, the method comprising:
forming an array of surface regions on a substrate;
applying a vapor-phase organic material to the array of surface regions; and
at each surface region, controlling at least one of the diffusivity and the rate of desorption of the surface region and growing at least one organic single crystal from the vapor-phase organic material, thereby forming an array of organic single crystals located at the surface regions and mitigating the formation of organic single crystals on the substrate.

18. The method of claim 17, further including manipulating the surface of the surface regions, prior to growing at least one organic single crystal, to orient the organic single crystals during growth thereof, thereby forming an array of oriented single crystals.

19. The method of claim 17, wherein controlling includes controlling at least one of: surface roughness of the surface region, molecular interaction between the surface region and the vapor-phase organic material, growth temperature and vacuum.

20. The method of claim 17, wherein growing at least one organic single crystal includes coupling the at least one single crystal to an electric circuit.

21. The method of claim 17, further including forming, at each surface region, source and drain regions for a transistor, wherein growing at least one organic single crystal includes growing the at least one single crystal between the source and drain regions to form a channel region of the transistor.

22. The method of claim 17, further including providing a gate electrode that is capacitively coupled to the single crystal channel region to control current flow between the source and drain regions.

23. A semiconductor device comprising:
a plurality of surface regions on a substrate, each surface region exhibiting diffusivity and rate of desorption characteristics that, relative to the substrate, facilitate the growth of organic semiconducting single crystals at the surface regions from a vapor-phase organic material under conditions that mitigate single crystal growth on the substrate; and
at each surface region, at least one semiconducting single crystal.

24. The device of claim 23,
wherein the surface regions are circuit electrodes,
wherein two of the surface region electrodes are electrically connected by at least one single crystal that forms a semiconducting channel between the electrodes, and
further including a gate arranged to switch the semiconducting channel for passing current between the electrodes.

25. The device of claim 23, wherein the surface regions include carbon nanotube bundles that interact with vapor-phase organic material via π-π interactions and topography characteristics that facilitate selective single crystal growth at the bundles.
